(19) United States
(12) Patent Application Publication
(10) Pub. No.: US 2007/0182573 A1
(43) Pub. Date: Aug. 9, 2007

(54) Detecting and Alarming Device

(75) Inventors: Chu-Mei Lin, Kaohsiung (TW); Yin-Shu Ling, Norwalk, CT (US)

Correspondence Address: SHOEMAKER AND MATTARE, LTD, 10 POST OFFICE ROAD - SUITE 110, SILVER SPRING, MD, 20910, US

(73) Assignee: Chu-Mei Lin, Kaohsiung City (TW)

(21) Appl. No.: 11/672,606

(22) Filed: Feb. 8, 2007

(30) Foreign Application Priority Data
Feb. 8, 2006 (TW) 095104171

(51) Int. Cl. G08B 17/10; G01R 35/00; G08B 29/00

(52) U.S. Cl. 340/632; 340/506; 702/85

(57) ABSTRACT

A detecting and alarming device is provided, that has a mainframe and a detecting set detachably coupled to the mainframe. The detecting set has a parameter calibrating and setting unit for setting a predetermined concentration parameter, in order for the detecting set to send a signal to an alarm module of the mainframe, when a concentration of an ambient object detected by a detecting element of the detecting set is equal to or exceeds the predetermined concentration parameter. It allows the alarm module to generate an alarming signal upon receipt of the signal transmitted from the detecting set and the detecting, set to be easily separated from/coupled to the mainframe for replacement purpose.

### BACKGROUND OF THE INVENTION

1. Field of the Invention

The present invention relates to detecting and alarm device, and, more particularly, to a detecting and alarming device for detecting an increase in concentration of an ambient object and generating an alarming signal for warming purpose.

2. Description of Related Art

General gas detector for detecting the existence of gases, such as inflammable gases, toxic gases, or liquid gases, and sounding an alarm are used to perform the detection of leakages, for personal protection. Relevant patented devices and techniques have been disclosed in, for example, U.S. Pat. Nos. 3,879,717, 4,112,356, 4,175,422, and 5,280,273.

U.S. Pat. No. 3,879,717 discloses a portable methane monitor and alarm system, featuring in a battery-operated type for the ease of hand-carry and employing a semiconductor type gas sensor to detect the concentration of methane gas and sound an alarm when an increase in concentration of methane gas has reached a predetermined value. U.S. Pat. No. 4,112,356 discloses a semiconductor gas detector circuit having a simplified temperature compensation circuit. U.S. Pat. No. 4,175,422 discloses an electric-heating type semiconductor detecting and alarming technique used for detecting the existence of toxic gases in an air ambient, such as carbon monoxide.

A major drawback of the foregoing known techniques lies in the combination of a sensing element and a control chip into the mainframe, and also the completion of the calibration and adjustment of alarm for detecting the concentration of gases in a finished product, because in practical applications, the signal outputs may be adversely affected due to an aged gas sensor. After being used continuously for a period of time, the aging of a gas sensor may result in the deviation of signals from the predetermined and original settings that can cause danger of the gas sensor to malfunction by failures to give out an alarm or a false alarm. Also, since a gas sensor is a key component of a gas detector, the integration of a sensing element in a mainframe becomes cost-ineffective in the case that a gas sensor alone has a breakdown.

To overcome the drawback as disclosed in prior arts, U.S. Pat. No. 5,280,273 discloses a toxic gas detection apparatus having convenient battery and sensor replacement, in which components of batteries and a sensing element are first configured in a housing and then combined with the mainframe so that the components can be replaced in future when required. In practical applications, however, this often necessitates the re-calibrating and re-setting of pre-determined values, such as the parameters for sounding an alarm in replacement of a sensing element, which usually requires professional staff with specific calibration equipment so as to perform the work, thereby causing inconvenience in maintenance and the replacement operation that in turn induces a high maintenance cost as a result.

Therefore, how to provide an improved gas detector alarm device having a simplified detecting module for replacement, which is capable of increasing the accuracy, safety, and convenience of the gas detection while reducing the cost, is a critical need in the art.

### SUMMARY OF THE INVENTION

In view of the above-mentioned problems of the prior art, it is a primary objective of the present invention to provide a detecting and alarming device having a replaceable detecting set, thereby effectively increasing the accuracy and safety in the detection of an ambient object.

It is another objective of the present invention to provide a detecting and alarming device having a replaceable detecting set, thereby desirably increasing the convenience in replacement of essential components.

Still another objective of the present invention is to provide a detecting and alarming device having a replaceable detecting set that is cost-effective when in use.

To achieve the above-mentioned and other objectives, a detecting and alarm device having a replaceable detecting set is provided according to the present invention. The detecting and alarm device comprises a mainframe having a first plugging portion and an alarm module electrically connected to the first plugging portion, and a detecting set having a detecting set having a second plugging portion for electrically and detachably connected to the first plugging portion; a detecting element electrically connected to the second plugging portion and for detecting a concentration of an ambient object; and a parameter calibrating and setting module electrically connected to element, wherein the parameter calibrating and setting module is capable of performing a calibration process to the detecting element and setting a predetermined concentration parameter of the ambient object, in order for the detecting element to send a control signal to the alarm module at the time that the concentration of the ambient object detected by the detecting alarm is equal to or exceeds the predetermined concentration parameter, thereby allowing the alarm module to send out a alarm signal upon receipt of the control signal.

Preferably, the first plugging portion in the detecting and alarm device includes a Universal Serial Bus (USB) interface. In one preferred embodiment, the alarm module comprises a warning indicator and an audio amplified driving circuit, and the warning indicator may be a flash audio warning element, such as a flashing light or a buzzer.

In another preferred embodiment, the mainframe of the detecting and alarm device may further selectively comprise a communication module for long-distance transmission, a control module electrically connected to the first plugging portion, a timing module electrically connected to the control module, and a power supply circuit for supplying power to the control module, wherein the communication module can be, for example, a wired or wireless long-distance transmission communication module. In one preferred embodiment, the control module may comprise a control chip for a detecting circuit of the detecting element; in another preferred embodiment, the control module may selectively comprise a Central Processing Unit (CPU), a register memory for allowing the CPU to store/retrieve data therein/therefrom, and a system status display circuit connected to the CPU.

Similarly, the second plugging portion can includes a Universal Serial Bus (USB) interface. The detecting element can be, for example, a semiconductor gas detector or other equivalent components. In one preferred embodiment, the parameter calibrating and setting module includes a built-in setting circuit or a memory chip for performing a calibration process to the detecting element and setting a predetermined concentration parameter of an ambient objects; in another preferred embodiment, the parameter calibrating and setting module comprises a microprocessor electrically connected to the second plugging portion, a built-in setting circuit or a memory chip for performing a calibration process to the detecting element and setting a predetermined concentration of an ambient object, a signal receiving unit electrically connected to the microprocessor, a signal comparison unit electrically connected to the microprocessor and the signal receiving unit, and a sensing degree adjusting circuit electrically connected to the microprocessor, the signal receiving unit, and the signal comparison unit.

The ambient object recited throughout the specification may be referred to as a gas, a liquid or a substance in a solid form.

In summary, the detecting and alarm device proposed by the present invention is characterized by using a detecting module that is detachable from the mainframe and in that the detecting module is capable of performing a calibration process, such that in case that the detecting element or the like has been long used and exceeded the maintenance period, or has a breakdown, a light indicator of the mainframe can be utilized in the status of warning and it requires only the replacement of the detecting set that is rectified and adjusted by the original supplier without having to discard the entire equipment as encountered in the prior art, and also, a user without specific skill can easily operate the system by plugging in and out directly. Compared to the prior art, the detecting and alarm device according to the present invention can effectively enhance the accuracy and safety in the detection, and further is cost-effective and convenient to use, thereby overcoming the drawbacks and offering advantages over the prior art.

### BRIEF DESCRIPTION OF DRAWINGS

The invention can be more fully understood by reading the following detailed description of the preferred embodiments, with reference made to the accompanying drawings, wherein:

FIG. 1 is a block diagram of a preferred embodiment of the detecting and alarm device according to the present invention;

FIG. 2 is a block diagram showing the configuration of FIG. 1;

FIG. 3 is a detailed block diagram showing the configuration of FIG. 2;

FIG. 4 is a flow chart illustrating a self-diagnosis of detecting and alarm device; and

FIG. 5 is a flow chart illustrating the operation of the detecting and alarm device.

### DETAILED DESCRIPTION OF PREFERRED EMBODIMENTS

The following illustrative embodiments are provided to illustrate the disclosure of the present invention, these and other advantages and effects being readily understood by those in the art after reading the disclosure of this specification. The present invention can also be performed or applied by other differing embodiments. The details of the specification may be modified on the basis of different points and applications, and numerous modifications and variations can be devised without departing from the spirit of the present invention.

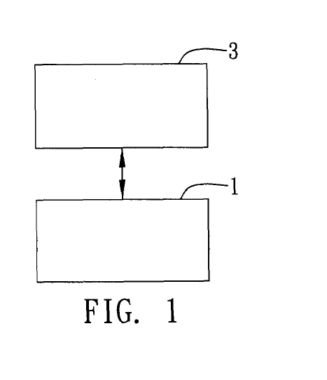

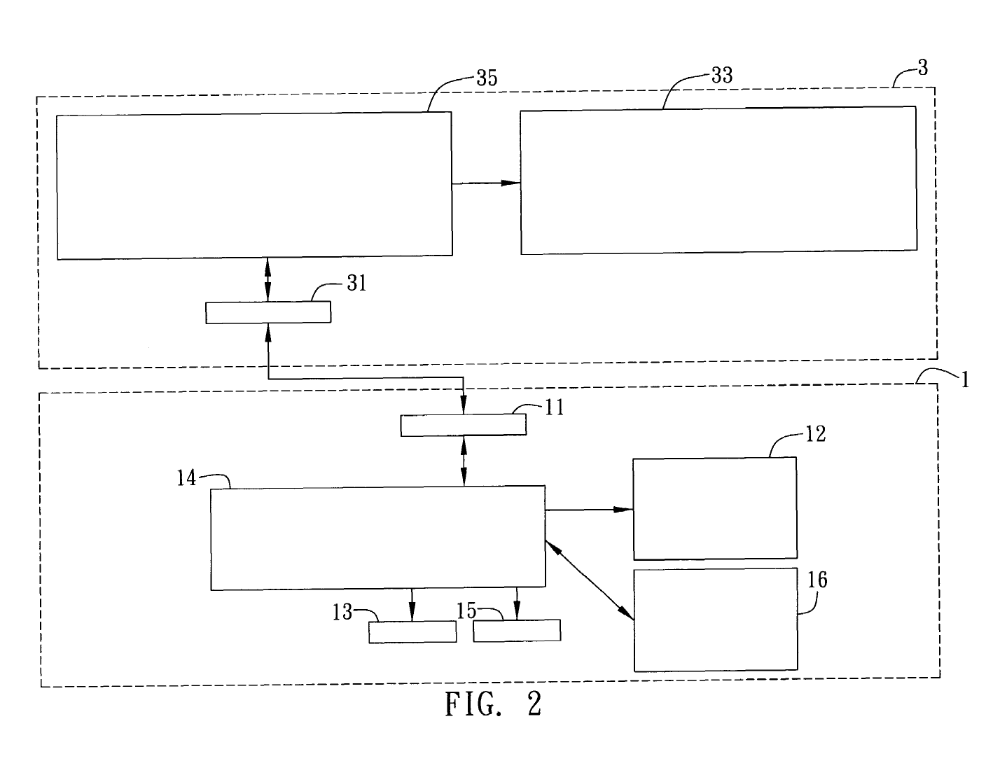

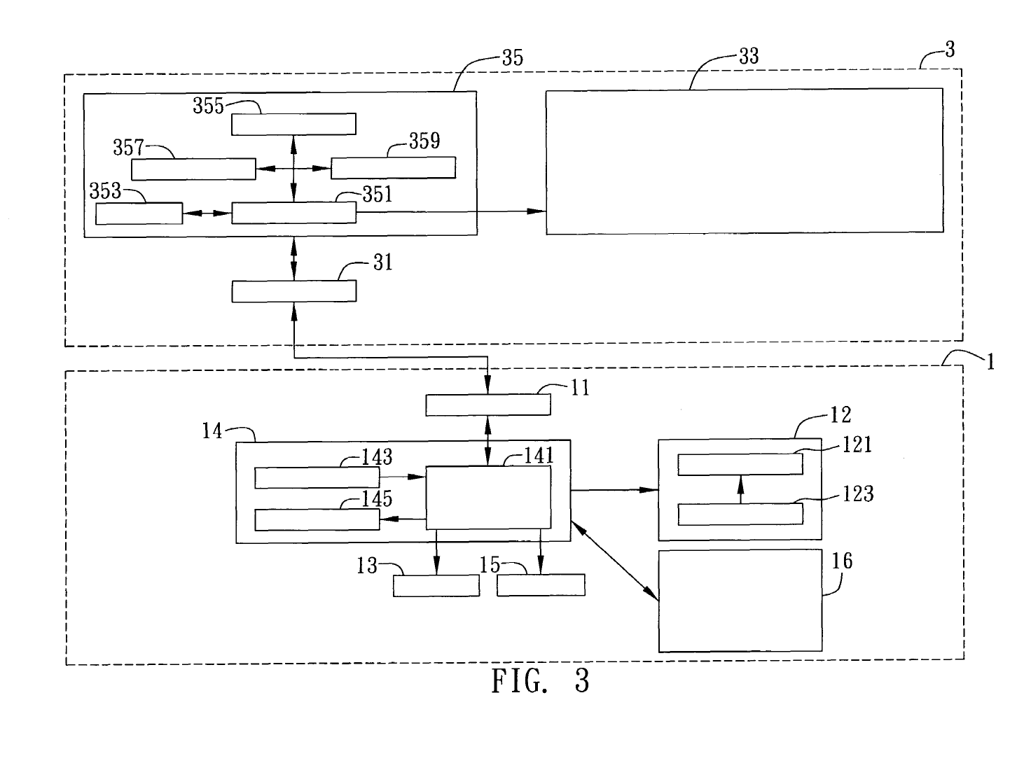

FIG. 1 is a block diagram of a preferred embodiment of the detecting and alarm device according to the present invention having a mainframe 1 and a detecting set 3 detachably coupled to the mainframe 1. Referring to FIG. 2, the mainframe 1 mainly consists of a first plugging portion 11 and an alarm module 12 electrically connected to the first plugging portion 11. The first plugging portion 11 comprises a USB interface but is not limited to the design. Referring to FIG. 3, in this embodiment, the alarm module 12 may selectively include an alarm indicator 121 and an audio amplified driving circuit 123, wherein the alarm indicator 121 can be a flash audio alarm indicator, for example, a flashing light having different colors or a buzzer having different alarm sounds, thereby displaying the warning and alarm of low gas concentration, of high gas concentration, or other types of warnings depending on the users' requirements.

In this embodiment, the mainframe 1 of the detecting and alarm device may further selectively comprise a communication module 13 for long-distance transmission communication, a control module electrically connected to the first plugging portion 11, a timing module 15 electrically connected to the control module 14, and a power supply circuit 16 for supplying power to the control module 14.

The communication module 13 can be, for example, a wired or wireless long-distance transmission communication module, so as to control remotely the detecting and alarming device and/or connect the device to other devices, such as those applied in security devices or medical devices. The control module 14 may comprise a control chip for a detecting circuit configured in the electing set 3 (not shown in the drawings) and/or other equivalent components having time-counting and self-diagnosis capabilities; in this preferred embodiment, the control module 14 may selectively comprise a CPU 141 electrically connected to the first plugging portion 11; a register memory 143 for allowing the CPU 141 to store/retrieve data therein/therefrom, and a system status display circuit 145 electrically connected to the CPU 141, thereby allowing the control module 14 to detect the lifetime of the detecting set 3, the condition of use, and to receive signals sent from the detecting set 3, and further after the proper handling of a situation, automatically send out a corresponding warning signal to the alarm module 12. The timing module 15 can count the time to calculate the lifetime of the detecting set 3.

Referring to FIG. 2, the detecting set 3 consists of a second plugging portion 31 for being detachably connected to the first plugging portion 11 of the mainframe 1, a detecting element 33 electrically connected to the second plugging portion 31, and a parameter calibrating and setting module 35 electrically connected to the detecting element 33. The second plugging portion 31 comprises a USB interface, and the parameter calibrating and setting module 35 may selectively include a built-in setting circuit or a memory chip for performing a calibration process to the detecting element 33 and setting a predetermined concentration parameter of a gas.

In the preferred embodiment, the parameter calibrating and setting module 35 may selectively comprise a microprocessor 351 electrically connected to the second plugging portion 31, a built-in memory chip 353 for performing a calibration process to the detecting element 33 and setting the predetermined concentration parameter, a signal receiving unit 355 electrically connected to the microprocessor 351, a signal comparison unit 357 electrically connected to the microprocessor 351 and the said signal receiving unit 355, and a sensing degree adjusting circuit 359 electrically connected to the microprocessor 351, the signal receiving unit 355, and the signal comparison unit 357. Also, predetermined parameters of the gas concentration can be pre-stored into the memory hip 353 in the fabrication of the parameter calibrating and setting module 35, such that when the detecting element 33 is being replaced, the parameter calibrating and setting module 35 can be provided parameters of the gas concentration rectification and alarm setting values without requiring the user to perform the rectification and setting of parameters. As the construction and operation of the rectification equipment and techniques of parameter settings are of known prior art, therefore it will not be further detailed herein.

It is to be noted that, in this embodiment, the second plugging portion 31 is a plug having a USB interface while the first plugging portion 11 is a socket having a USB interface, allowing said sensing module 3 to pluggably connect to said mainframe 1. Similarly, in other embodiments, it can be that the first plugging portion 11 is a socket while the second plugging portion 31 is a plug, or the first plugging portion 11 and the second plugging portion 31 are different structures that are pluggable to combine as one or more structures having other electrical connection interface, so long as the chosen structure can electrically connect to the detecting set 3 and the mainframe 1. In other words, although it is exemplified in this embodiment as a plug and a socket having a USB interface, other equivalent structures having an electrical connection interface can be employed by persons having ordinary skills in the art, and is not to be limited to that of the embodiment.

In application of the detecting and alarm device, the detecting element 33 of the detecting set 3 detects the concentration of the gas to be detected in an ambient environment, and a control signal is then sent by the second plugging portion 31 to the mainframe 1. Also, the detecting and alarm device may perform a self-diagnosis prior to the detection of the gas concentration to ensure that the system is functioning normally.

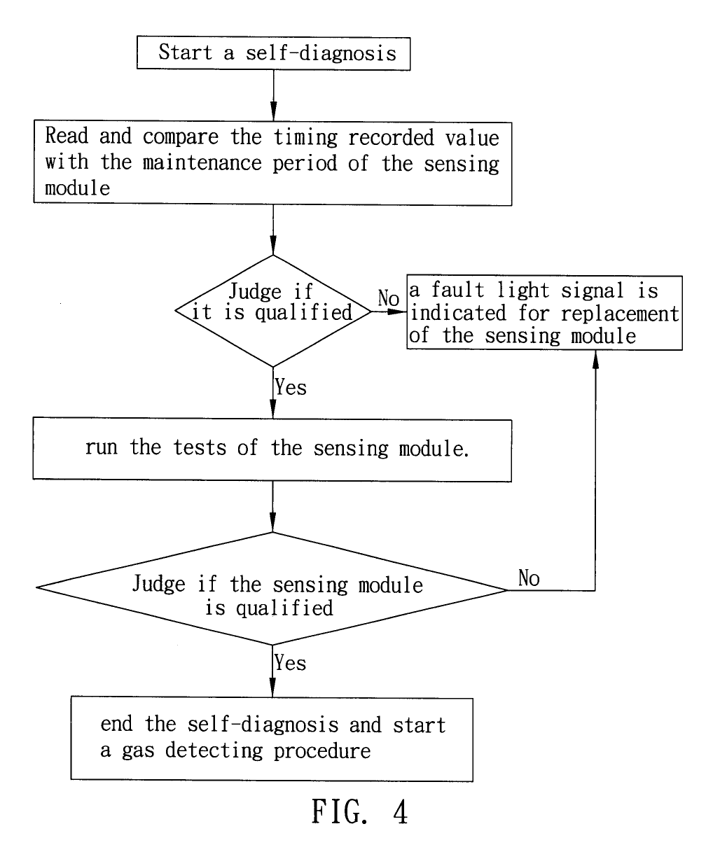

For example, in one aspect of embodiment, a self-diagnosis process of the detecting and alarm device is illustrated in FIG. 4, in which the time-counting module 15 calculates the maintenance period of the detecting set 3, the CPU 141 reads the recorded value of the lifetime stored in the register memory 143 and compares the calculated maintenance period with the recorded value of lifetime to determine if the maintenance period of the detecting set 3 is due. If the maintenance period is due, the detecting set 3 is determined unqualified, whereas if the maintenance period is yet due the detecting set 3 is determined qualified. When the detecting set 3 is determined unqualified (NO), a light signal may be used to indicate that the replacement of the detecting set 3 is necessary; and when the detecting set 3 is determined qualified (YES), process may continue to test whether the function of the detecting set 3 is normal. The detecting set 3 is determined qualified if it turns out to function normally, whereas otherwise, the detecting set 3 is deemed unqualified (NO) and in this case, a light signal may be utilized to indicate that the replacement of the detecting set 3 is necessary; whereas when the detecting set 3 is deemed qualified (YES), the self-diagnosis process is terminated for conducting the subsequent gas detection process.

In one aspect of embodiment, said CPU 141 may send out a warning signal to the alarm module 12 by means of an automatic warning light signal or an audio sound to inform the user of the necessity of replacing the detecting set 3; or, in a self-diagnosis process that the detecting set 3 is detected to have a breakdown or exceed the maintenance period, the status display circuit 145 and/or the alarm module 12 may send a message informing the user of the necessity of the maintenance or replacement; or the self-diagnosis process may be performed to detect whether other components or modules are qualified and that the status display circuit 145 and/or the alarm module 12 may display a message informing the user of the necessity of the maintenance or replacement.

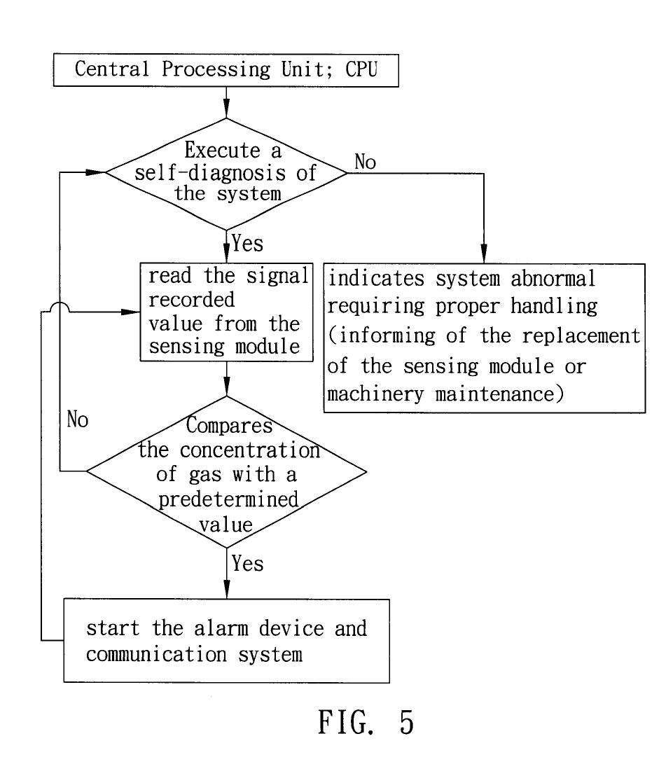

In one aspect of the embodiment, the operational flow of the detecting and alarm device is exemplified in FIG. 5, in which the CPU 141 conducts the process of a system self-diagnosis. When the device is indicated to be abnormal (NO), the status display circuit 145 proceeds to notify the user to replace the detecting set 3 or other components and modules that need to be replaced; and when the device is indicated to be normal (YES), the signal recorded value of the detecting set 3 is read and compared with a predetermined parameter of the gas concentration by the control module 14. Thereafter, if the recorded signal value obtained from the detecting set 3 is determined to not reach the predetermined parameter of the gas concentration (NO), the CPU proceeds to conduct the process of a system self-diagnosis; whereas if the recorded signal value is determined to reach the predetermined parameter of the gas concentration (YES), the CPU actuates the alarm module 12 and the communication module 13 thereof to report and notify of the result accordingly.

Further, data relating to the safety guarantee period and function tests of the sensing element 33 of the detecting set 3 may be stored and set in the mainframe 1, and the timing module 15 and/or said status display circuit 145 may send out a corresponding signal to the CPU 141, effectively controlling and also reminding the user of the necessity of replacing the detecting set 3. Thereby, the mainframe 1 can be reliably used for a long time and also the accuracy and safety of the detecting and alarm device is increased to ensure the safety of the users' life and property.

Additionally, the detecting and alarm device can be provided with a test system (not shown) to test the concentration of carbon monoxide. In testing the system, a 110V power supply is plugged in so that said sensing module 3 is driven by the mainframe 1 to automatically clean for 60 seconds, acquire signals, compare the acquired signals with the built-in setting value, start the detection for a cycle of one minute feedback continuously.

For example, in an alarm test of the low concentration of gas, after the test system passes the gas concentration of carbon monoxide at 150 PPM, the flash time of a low gas concentration warning light of said alarm module 12 is recorded as, for example, 58 seconds, 55 seconds, 51 seconds, 48 seconds and 46 seconds respectively. If the test result conforms to the test specification, gas of carbon monoxide is dispersed by ventilation and the flash alarm of the warning light stops immediately after a reset key is pressed. In a test environment where the gas concentration of carbon monoxide remains at 150 PPM, if a warning light keeps flashing in every test cycle of one minute after the reset key has been pressed, it indicates that the carbon monoxide gas still remains in the test environment.

On the other hand, in a high gas concentration alarm test, after the test system passes 320 PPM of carbon monoxide, the flash time of the high gas concentration warning light of said alarm module 12 is recorded as, for example, 55 seconds, 53 seconds, 52 seconds, 48 seconds, and 45 seconds respectively. If the test result conforms to the test specification, an alarm signal is automatically sent out by a communication function of the device, gas of carbon monoxide is dispersed by ventilation and the flash alarm of the warning light stops immediately after a reset key is pressed. In a test environment where the gas concentration of carbon monoxide remains at 150 PPM, if a warning light keeps flashing and sounding alarms in every test cycle of one minute after the reset key has been pressed, it indicates that a high concentration of the carbon monoxide gas still remains in the test environment. Accordingly, the test results according to the above tests prove to be highly reliable and the device can overcome the defects of the deteriorating worn gas sensors that causes signals to deviate from original setting values and malfunctions of non-alarms or false-alarms.

Compared to the prior art, the detecting and alarm device features in a detecting set that is detachable from the mainframe and preset parameters stored in the detecting set, such that the mainframe can be continuously and safely used for a long time, which is environmental and user-friendly in that a user can easily replace the sensing module having a communication connection capability for connecting to security systems as required. The detecting and alarm device yields great benefits in that it is applicable to the detection of gas and carbon monoxide in households and also is suitable for industrial use to effectively enhance the accuracy and safety, and it is cost-effective and convenient to use, thereby overcoming the drawbacks and offering advantages over prior art techniques.

The foregoing descriptions of the detailed embodiments are illustrated to disclose the features and functions of the present invention and are not restrictive of the scope of the present invention. It should be understood by those in the art that various modifications and variations can be made to the present invention according to the spirit and principle in the disclosure and yet fall within the scope of the appended claims.

We claim:

1. A detecting and alarming device, comprising:
a mainframe having a first plugging portion and an alarm module electrically connected to the first plugging portion; and
a detecting set having a second plugging portion for being pluggably connected to the first plugging portion of the mainframe, a detecting element electrically connected to the second plugging portion, and a parameter calibrating and setting module electrically connected to the detecting element, wherein the parameter calibrating and setting module is capable of performing a calibration process to the detecting element and setting a predetermined concentration parameter of an ambient object, in order for the detecting element to send a control signal to the alarm module at the time that a concentration of the ambient object detected by the detecting element is equal to or exceeds the predetermined concentration parameter, thereby allowing the alarm module to generate an alarming signal upon receipt of the control signal.

2. The detecting and alarming device of claim 1, wherein the first plugging portion has a Universal Serial Bus (USB) interface.

3. The detecting and alarming device of claim 1, wherein the alarm module has an alarm element and an audio amplified driving circuit.

4. The detecting and alarming device of claim 3, wherein the alarm element is a flash audio warning member.

5. The detecting and alarming device of claim 3, wherein the alarm element is a flashing light or a buzzer.

6. The detecting and alarming device of claim 1, wherein the mainframe further comprises a communication module for long-distance transmission communication, a control module electrically connected to the first plugging portion, a timing module electrically connected to the control module, and a power supply circuit for supplying power to the control module.

7. The detecting and alarming device of claim 6, wherein the communication module is designed for carrying out wired/wireless long-distance transmission communication.

8. The detecting and alarming device of claim 6, wherein the control module comprises a control chip for a detecting circuit of the detecting element.

9. The detecting and alarming device of claim 6, wherein the control module comprises a Central Processing Unit (CPU), a register memory for allowing the CPU to store/retrieve data therein/therefrom, and a system status display circuit connected to the CPU.

10. The detecting and alarming device of claim 1, wherein the second plugging portion has a Universal Serial Bus (USB) interface.

11. The detecting and alarming device of claim 1, wherein the detecting element is a semiconductor detector.

12. The detecting and alarming device of claim 1, wherein the parameter calibrating and setting module comprises a built-in setting circuit or a memory chip for performing the calibration process to the detecting element and setting the predetermined concentration parameter.

13. The detecting and alarming device of claim 1, wherein the parameter calibrating and setting module comprises a microprocessor electrically connected to the second plugging portion, a built-in setting circuit or a memory chip for performing the calibration process to the detecting element and setting the predetermined concentration parameter, a signal receiving unit electrically connected to the microprocessor, a signal comparison unit electrically connected to the microprocessor and signal receiving unit, and a sensing degree adjusting circuit electrically connected to the microprocessor, signal receiving unit, and signal comparison unit.
